(19) United States
(12) Patent Application Publication
(10) Pub. No.: US 2024/0379481 A1
(43) Pub. Date: Nov. 14, 2024

(54) SEMICONDUCTOR PACKAGE INCLUDING A PLURALITY OF CHIPS SEQUENTIALLY STACKED ON A PACKAGE SUBSTRATE BY AN ADHESIVE FILM AND METHOD OF MANUFACTURING THE SEMICONDUCTOR PACKAGE

(71) Applicant: SAMSUNG ELECTRONICS CO., LTD., SUWON-SI (KR)

(72) Inventor: Eunsu LEE, Suwon-si (KR)

(21) Appl. No.: 18/619,512

(22) Filed: Mar. 28, 2024

(30) Foreign Application Priority Data
May 12, 2023 (KR) 10-2023-0061789

(51) Int. Cl. H01L 23/31; H01L 23/00; H01L 23/498; H01L 25/065

(52) U.S. Cl. CPC H01L 23/3135; H01L 23/3128; H01L 23/49838; H01L 24/16; H01L 24/29; H01L 24/32; H01L 24/48; H01L 24/73; H01L 25/0657; H01L 2224/16227; H01L 2224/26175; H01L 2224/32145; H01L 2224/32225; H01L 2224/48227; H01L 2224/73204; H01L 2224/73253; H01L 2224/73265

(57) ABSTRACT

A semiconductor package includes: a package substrate having an upper surface and a receiving groove that has a predetermined depth from the upper surface; a first semiconductor chip disposed in the receiving groove; a second semiconductor chip attached to the first semiconductor chip, wherein the second semiconductor chip does not overlap a portion of the first semiconductor chip; an underfill member filling the receiving groove of the package substrate, wherein the underfill member includes a first cover portion and a second cover portion, wherein the first cover portion fills a gap between the first semiconductor chip and a bottom surface of the receiving groove, and the second cover portion covers the portion of the first semiconductor chip that is not overlapped by the second semiconductor chip; and a molding member covering the first semiconductor chip, the second semiconductor chip and the underfill member and disposed on the package substrate.

### CROSS-REFERENCE TO RELATED APPLICATION

This application claims priority under 35 U.S.C. § 119 to Korean Patent Application No. 10-2023-0061789, filed on May 12, 2023 in the Korean Intellectual Property Office (KIPO), the disclosure of which is hereby incorporated by reference herein in its entirety.

### TECHNICAL FIELD

Example embodiments of the present inventive concept relate to a semiconductor package and a method of manufacturing the semiconductor package. More particularly, example embodiments of the present inventive concept relate to a semiconductor package including a plurality of chips sequentially stacked on a package substrate by an adhesive film and a method of manufacturing the same.

### DISCUSSION OF THE RELATED ART

Generally, in a Hybrid System In Package, a lower semiconductor chip may be mounted on a package substrate by using a flip chip method, and an upper semiconductor chip may be mounted on the package substrate by using an adhesive film such as a die attach film (DAF) and by using a wire bonding method. During a molding process, the adhesive film may be lifted or pushed away from the lower semiconductor chip due to the heat and pressure that pushes epoxy mold compound (EMC), causing EMC to enter the gap between the adhesive film and the lower semiconductor chip, which may result in process defects or voids being trapped, resulting in poor reliability of the semiconductor package.

### SUMMARY

According to example embodiments of the present inventive concept, a semiconductor package includes: a package substrate having an upper surface and a lower surface opposite the upper surface, wherein the package substrate has a receiving groove that has a predetermined depth from the upper surface; a first semiconductor chip disposed in the receiving groove of the package substrate, wherein a first surface of the first semiconductor chip faces the package substrate, and first chip pads are formed on the first surface; a second semiconductor chip attached to a second surface opposite to the first surface of the first semiconductor chip by an adhesive film, wherein the second semiconductor chip does not overlap a portion of the second surface of the first semiconductor chip; an underfill member filling the receiving groove of the package substrate, wherein the underfill member includes a first cover portion and a second cover portion, wherein the first cover portion fills a gap between the first semiconductor chip and a bottom surface of the receiving groove, and the second cover portion covers the portion of the second surface of the first semiconductor chip that is not overlapped by the second semiconductor chip; and a molding member covering the first semiconductor chip, the second semiconductor chip and the underfill member and disposed on the package substrate.

According to example embodiments of the present inventive concept, a semiconductor package includes: a package substrate having a receiving groove that has a predetermined depth from on an upper surface of the package substrate; a first semiconductor chip disposed in the receiving groove of the package substrate; a second semiconductor chip attached to an upper surface of the first semiconductor chip by an adhesive film to expose a portion of the upper surface of the first semiconductor chip; an underfill member filling the receiving groove of the package substrate, wherein the underfill member includes a first cover portion, a second cover portion, and a third cover portion, wherein the first cover portion fills a gap between the first semiconductor chip and the bottom of the receiving groove, wherein the second cover portion covers the portion of the upper surface of the first semiconductor chip that is exposed by the second semiconductor chip, and the third cover portion covers a gap between the first semiconductor chip and a sidewall of the receiving groove; and a molding member covering the first semiconductor chip, the second semiconductor chip, and the underfill member and disposed on the package substrate.

According to example embodiments of the present inventive concept, a semiconductor package includes: a package substrate having a receiving groove that has a predetermined depth from an upper surface of the package substrate; a first semiconductor chip disposed in the receiving groove of the package substrate, wherein a first surface of the first semiconductor chip faces the package substrate, wherein first chip pads are disposed on the first surface of the first semiconductor chip, wherein the first semiconductor chip is mounted on first substrate pads through conductive bumps that are formed on the first chip pads of the first semiconductor chip, wherein the first substrate pads are disposed on the bottom surface of the receiving groove; a second semiconductor chip attached on a second surface opposite to the first surface of the first semiconductor chip by an adhesive film to expose a portion of the second surface of the first semiconductor chip, wherein a fourth surface of the second semiconductor chip faces the first semiconductor chip, and second chip pads are formed on a third surface, opposite to the fourth surface, of the second semiconductor chip; an underfill member filling the receiving groove of the package substrate, wherein the underfill member includes a first cover portion and a second cover portion, wherein the first cover portion fills a gap between the first semiconductor chip and the bottom surface of the receiving groove, and the second cover portion covers the portion of the second surface of the first semiconductor chip that is exposed by the second semiconductor chip; and a molding member covering the first semiconductor chip, the second semiconductor chip, and the underfill member and disposed on the package substrate, wherein a thickness of the second cover portion of the underfill member is within a range of about 5 μm to about 30 μm.

### BRIEF DESCRIPTION OF THE DRAWINGS

The above and other features of the present inventive concept will become more apparent by describing in detail example embodiments thereof, with reference to the accompanying drawings, in which:

FIG. 1 is a cross-sectional view illustrating a semiconductor package in accordance with example embodiments of the present inventive concept.

FIG. 2 is a plan view of FIG. 1.

FIGS. 3, 4, 5, 6, 7, 8, 9, 10, 11, and 12 are views illustrating a method of manufacturing a semiconductor package in accordance with example embodiments of the present inventive concept.

FIG. 13 is a cross-sectional view illustrating a semiconductor package in accordance with example embodiments of the present inventive concept.

FIG. 14 is a plan view of FIG. 13.

FIGS. 15, 16, 17 and 18 are views illustrating a method of manufacturing a semiconductor package in accordance with example embodiments of the present inventive concept.

FIG. 19 is a cross-sectional view illustrating a semiconductor package in accordance with example embodiments of the present inventive concept.

FIG. 20 is a plan view of FIG. 19.

### DETAILED DESCRIPTION OF EXAMPLE EMBODIMENTS

Hereinafter, example embodiments of the present inventive concept will be described in detail with reference to the accompanying drawings.

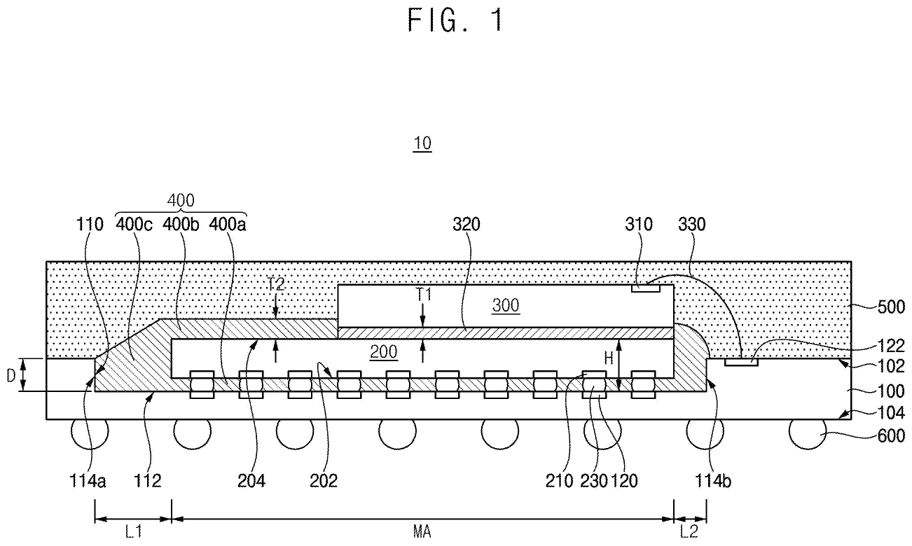

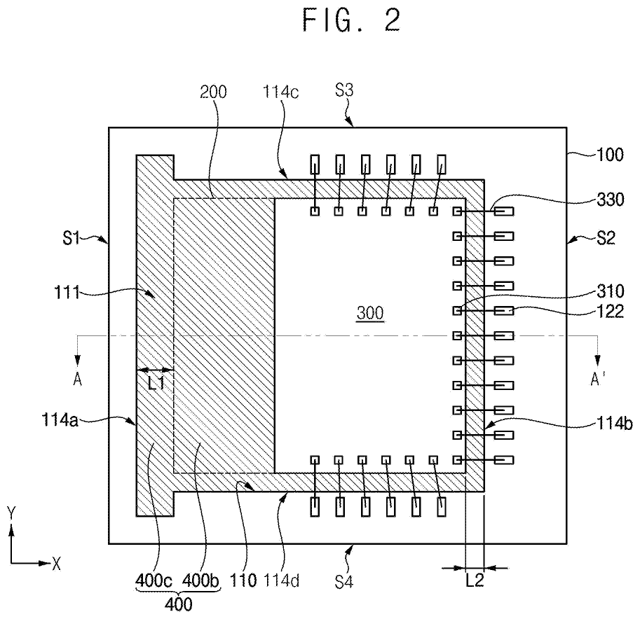

FIG. 1 is a cross-sectional view illustrating a semiconductor package in accordance with example embodiments of the present inventive concept. FIG. 2 is a plan view of FIG. 1. FIG. 1 is a cross-sectional view taken along the line A-A′ in FIG. 2. FIG. 2 is a plan view illustrating the semiconductor package in FIG. 1, wherein a molding member is omitted.

Referring to FIGS. 1 and 2, a semiconductor package 10 may include a package substrate 100 having a receiving groove 110, a first semiconductor chip 200, a second semiconductor chip 300, an underfill member 400, and a molding member 500. The first semiconductor chip 200 may be disposed in the receiving groove 110 of the package substrate 100, and the second semiconductor chip 300 may be disposed on an upper surface of the first semiconductor chip 200. The underfill member 400 may fill the receiving groove 110 and may cover at least a portion of the upper surface of the first semiconductor chip 200, and the molding member 500 may cover the first semiconductor chip 200, the second semiconductor chip 300 and the underfill member 400 on the package substrate 100. The semiconductor package 10 may further include conductive connection members 230 and 330 that electrically connect the first semiconductor chip 200 and the second semiconductor chip 300 to the package substrate 100. Additionally, the semiconductor package 10 may further include external connection members 600.

Additionally, the semiconductor package 100 may be a multi-chip package (MCP) including semiconductor chips of the same or different types. For example, the semiconductor package 100 may be a System In Package (SIP) including a plurality of semiconductor chips stacked or variously arranged in a single package, but being capable of performing a multiple functions associated with an electronic system. For example, the semiconductor package 100 may be a modem system-in-package having a modem for mobile phone communication.

In example embodiments of the present inventive concept, the package substrate 100 may have an upper surface 102 and a lower surface 104 that are opposite to each other. For example, the package substrate 100 may include a printed circuit board (PCB), a flexible substrate, a tape substrate, etc. The printed circuit board may be a multilayer circuit board having vias, conductive layers, and various circuits therein. The package substrate 100 may include internal wirings for electrical connection between the first semiconductor chip 200 and the second semiconductor chip 300.

The package substrate 100 may include a first side portion S1 and a second side portion S2 extending in a direction perpendicular to the upper surface 102 and parallel to a second direction (Y direction). In addition, the first side portion S1 faces the second side portion S2. The package substrate 100 may additionally include a third side portion S3 and a fourth side portion S4 extending in a direction parallel to a first direction (X direction) that is substantially perpendicular to the second direction (Y direction) and facing each other.

The package substrate 100 may have a receiving groove 110 that has a predetermined depth D from the upper surface 102 of the package substrate 100. When viewed in a plan view, the receiving groove 110 may have a shape corresponding to a shape of the first semiconductor chip 200. The receiving groove 110 may have a polygonal shape such as a rectangular shape. The receiving groove 110 includes a first sidewall 114a, a second sidewall 114b, a third sidewall 114c, and a fourth sidewall 114d. The first sidewall 114a may be adjacent to the first side portion S1, and the second sidewall 114b may be adjacent to the second side portion S2. The third sidewall 114c may be adjacent to the third side portion S3, and the fourth sidewall 114d may be adjacent to the fourth side portion S4.

For example, the depth D of the receiving groove 110 may be within a range of about 8 μm to about 20 μm. The depth, location, planar area, etc. of the receiving groove 110 may be determined in consideration of a thickness and planar area of the first semiconductor chip 200 and a thickness of the underfill member 400. For example, the depth, location, planar area, etc. of the receiving groove 110 may also be determined in consideration of a thickness and planar area of the second semiconductor chip 300 and the molding member 500.

The receiving groove 110 may have a chip mounting region MA in a central portion in which the first semiconductor chip 200 is mounted. The chip mounting region MA may have a rectangular shape corresponding to the shape of the first semiconductor chip 200.

The package substrate 100 may include first substrate pads 120 and second substrate pads 122. The first substrate pads 120 may be for electrical connection with the first semiconductor chip 200, and the second substrate pads 122 may be for electrical connection with the second semiconductor chip 300. The first substrate pads 120 may be provided in the chip mounting region MA on a bottom surface 112 of the receiving groove 110. The first substrate pads 120 may be arranged in an array form within the chip mounting region MA. The second substrate pads 122 may be provided on the upper surface 102 of the package substrate 100 along the second, third and fourth side portions S2, S3 and S4. The first and second substrate pads 120 and 122 may be respectively connected to the wirings. The wirings may extend from the upper surface 102 or inside the package substrate 100. For example, at least a portion of the wiring may be used as a landing pad or as a substrate pad on the package substrate 100.

Although only some substrate pads are illustrated in the figures, it will be understood that the number, shape, and arrangement of the substrate pads are provided as examples, and the present inventive concept is not limited thereto.

A first insulating layer may be formed on the upper surface 102 of the package substrate 100 and the bottom surface 112 of the receiving groove 110 to expose the first and second substrate pads 120 and 122. The first insulating layer may cover the entire upper surface 102 of the package substrate 100 excluding the first and second substrate pads 120 and 122. For example, the first insulating layer may include solder resist.

In example embodiments of the present inventive concept, the first semiconductor chip 200 may be mounted on the mounting region MA within the receiving groove 110 of the package substrate 100 via conductive bumps 230. The first semiconductor chip 200 may be disposed such that a front surface 202 thereof faces the package substrate 100, and the first chip pads 210 may be disposed on the front surface 202, which may be referred to as an active surface. The first semiconductor chip 200 may have a rectangular shape with four sides when viewed in plan view. The first chip pads 210 may be arranged in an array form on the front surface 202 of the first semiconductor chip 200.

The first semiconductor chip 200 may be, for example, a logic chip including a logic circuit. The logic chip may be a controller that controls memory chips. The first semiconductor chip 200 may be a processor chip such as ASIC, an application processor (AP), etc. serving as a host such as a CPU, GPU, or SOC. The first semiconductor chip 200 may include, for example, a central processing unit (CPU), a graphics processing unit (GPU), and/or a modem. For example, the first semiconductor chip 200 may be implemented as a modem die or a modem die supporting a WCDMA (Wideband Code Division Multiple Access) communication method, but the present inventive concept is not limited thereto.

The first semiconductor chip 200 may be mounted on the package substrate 100 using a flip chip bonding method. The first chip pads 210 of the first semiconductor chip 200 may be electrically connected to the first substrate pads 120 of the package substrate 100 by the conductive connection members 230, for example, solder bumps.

For example, a thickness of the first semiconductor chip 200 may be within a range of about 40 μm to about 110 μm. The first semiconductor chip 200 may have a predetermined height H from the bottom surface 112 of the receiving groove 110 to the upper surface 204 of the first semiconductor chip 200. The height H of the first semiconductor chip 200 may be within a range of about 50 μm to about 110 μm. The first semiconductor chip 200 may protrude from the upper surface 102 of the package substrate 100.

When viewed in plan view, a first distance L1 between the first semiconductor chip 200 and the first sidewall 114a of the receiving groove 110 may be greater than a second distance L2 between the first semiconductor chip 200 and the second sidewall 114b of the receiving groove 110. As will be described later, a supply portion 111 through which an aqueous underfill solution is supplied may be provided between the first semiconductor chip 200 and the first sidewall 114a of the receiving groove 110. For example, the first distance L1 between the first semiconductor chip 200 and the first sidewall 114a of the receiving groove 110 may be within a range of about 100 μm to about 250 μm.

In example embodiments of the present inventive concept, the second semiconductor chip 300 may be attached to the first semiconductor chip 200 using an adhesive film 320. The second semiconductor chip 300 may be attached to a backside surface of the first semiconductor chip 200 by using the adhesive film 320 such as a die attach film (DAF) by a die attach process. The second semiconductor chip 300 may be disposed such that the backside surface thereof faces the first semiconductor chip 200, and second chip pads 310 may be disposed on a front surface of the second semiconductor chip 300, opposite to the backside surface. The backside surface may be an inactive surface. The second semiconductor chip 300 may have a rectangular shape with four sides when viewed in plan view.

For example, a thickness of the second semiconductor chip 300 may be within a range of about 40 μm to about 110 μm. A thickness T1 of the adhesive film 320 may be within a range of about 10 μm to about 30 μm. The second semiconductor chip 300 may include, for example, a memory chip including a memory circuit. For example, the second semiconductor chip may include volatile memory devices such as SRAM devices, DRAM devices, and non-volatile memory devices such as flash memory devices, PRAM devices, MRAM devices, RRAM devices.

In example embodiments of the present inventive concept, the second semiconductor chip 300 may be stacked to expose a portion of the upper surface 204 of the first semiconductor chip 200. For example, an area of the second semiconductor chip 300 may be less than an area of the first semiconductor chip 200. An outer surface of the second semiconductor chip 300 and an outer surface of the first semiconductor chip 200 adjacent to the second sidewall 114b of the receiving groove 110 may be positioned on the same plane. Accordingly, the second semiconductor chip 300 may expose a side portion of the first semiconductor chip 200 adjacent to the first sidewall 114a of the receiving groove 110.

In example embodiments of the present inventive concept, the second semiconductor chip 300 may be offset-aligned in a horizontal direction on the first semiconductor chip 200. The second semiconductor chip 300 may be offset-aligned in the second direction (X direction) to expose one side portion of the first semiconductor chip 200 adjacent to the first sidewall 114a of the receiving groove 110. For example, a center of the second semiconductor chip 300 may be misaligned with a center of the first semiconductor chip 200.

The second semiconductor chip 300 may be mounted on the package substrate 100 using a wire bonding method. The second chip pads 310 of the second semiconductor chip 300 may be electrically connected to the second substrate pads 122 that are disposed on the upper surface 102 of the package substrate 100 by conductive connection members 330 such as bonding wires.

It will be understood that the number, size, arrangement, mounting method, etc. of the first and second semiconductor chips are provided as examples, and the present inventive concept is not limited thereto. In addition, although some first and second chip pads are illustrated in the figures, it should be understood that the structure, shape and arrangement of the first and second chip pads are provided as examples, and the present inventive concept is not limited thereto.

In example embodiments of the present inventive concept, the underfill member 400 may include a first cover portion 400a and a second cover portion 400b. The first cover portion 400a may fill the receiving groove 110 and fill a gap between the first semiconductor chip 200 and the bottom surface 112 of the receiving groove 110, and the second cover portion 400b may cover a portion of the upper surface 204 of the semiconductor chip 200 exposed by the second semiconductor chip 300. The underfill member 400 may further include a third cover portion 400c that fills a gap between the first semiconductor chip 200 and the first to fourth sidewalls 114a, 114b, 114c, and 114d of the receiving groove 110. For example, the underfill member 400 may include a thermosetting resin such as epoxy resin.

The first cover portion 400a may fill gaps between the conductive bumps 230 that are disposed between the first semiconductor chip 200 and the bottom surface 112 of the receiving groove 100. The second cover portion 400b may cover a side surface of the adhesive film 320 that is disposed below the second semiconductor chip 300. The second cover portion 400b may cover at least a portion of the lower sidewall of the second semiconductor chip 300. For example, a thickness T2 of the second cover portion 400b may be within a range of about 5 μm to about 30 μm. The third cover portion 400c may cover the outer surface of the first semiconductor chip 200. For example, the third cover portion 400c may cover the entire outer surface of the first semiconductor chip 200.

In example embodiments of the present inventive concept, the molding member 500 may cover the first semiconductor chip 200, the second semiconductor chip 300, the underfill member 400, and the bonding wires 330 and may be disposed on the upper surface 102 of the package substrate 100. The molding member may include a thermosetting resin, for example, epoxy mold compound (EMC). The molding member 500 may be formed through a molding process using a transfer mold.

In example embodiments of the present inventive concept, external connection pads for providing electrical signals may be formed on the lower surface 104 of the package substrate 100. The external connection pads may be exposed by a second insulating layer. The second insulating layer may include, for example, a silicon oxide layer, a silicon nitride layer, or a silicon oxynitride layer. External connection members 600 may be disposed on the external connection pads of the package substrate 100 for electrical connection with external devices. For example, the external connection member 600 may be a solder ball. For example, the semiconductor package 10 may be mounted on a module substrate by using the solder balls to form a semiconductor module.

As mentioned above, the semiconductor package 10 may include the first semiconductor chip 200, the second semiconductor chip 300, the underfill member 400, and the molding member 500. The first semiconductor chip 200 may be disposed in the receiving groove 110 of the package substrate 100, and the second semiconductor chip 300 may be attached to the upper surface 204 of the first semiconductor chip 200 by the adhesive film 320 to expose the portion of the upper surface 204 of the first semiconductor chip 200. The underfill member 400 may fill the receiving groove 110 of the package substrate 100 and may cover the portion of the upper surface 204 of the first semiconductor chip 200 that is exposed by the second semiconductor chip 300, and the molding member 500 may cover the first semiconductor chip 200, the second semiconductor chip 300 and the underfill member 400 and may be disposed on the package substrate 100.

The second cover portion 400b of the underfill member 400 may cover the portion of the upper surface 204 of the first semiconductor chip 200 that is exposed by the second semiconductor chip 300 and may cover the side surface of the adhesive film 320 that is disposed below the second semiconductor chip 300, and accordingly, it may be possible to prevent the adhesive film 320 from being peeled off from the first semiconductor chip 200 when the molding member 500 is formed by the molding process by using the transfer mold.

Thus, the underfill member 400 may prevent EMC defects due to interfacial peeling between the adhesive film 320 and the first semiconductor chip 200 during the transfer molding process to thereby increase the mechanical reliability of the semiconductor package 10.

Hereinafter, a method of manufacturing the semiconductor package of FIG. 1 will be described.

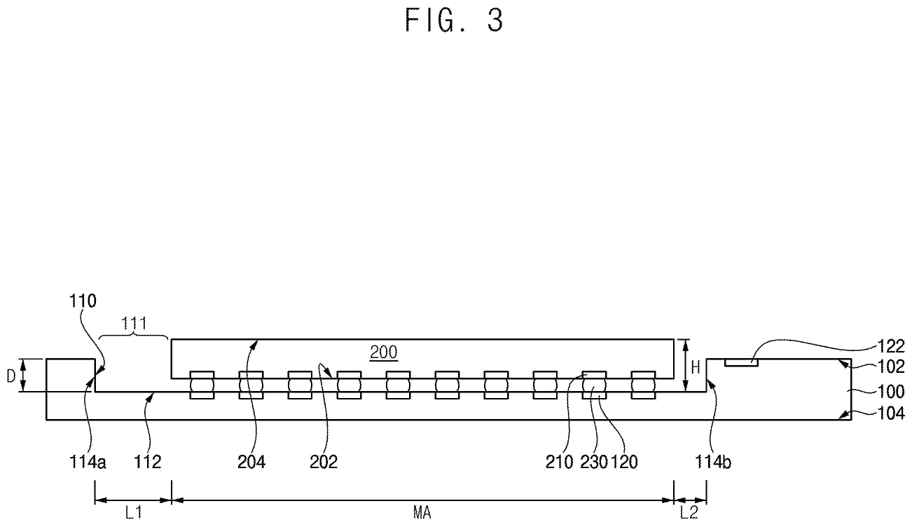

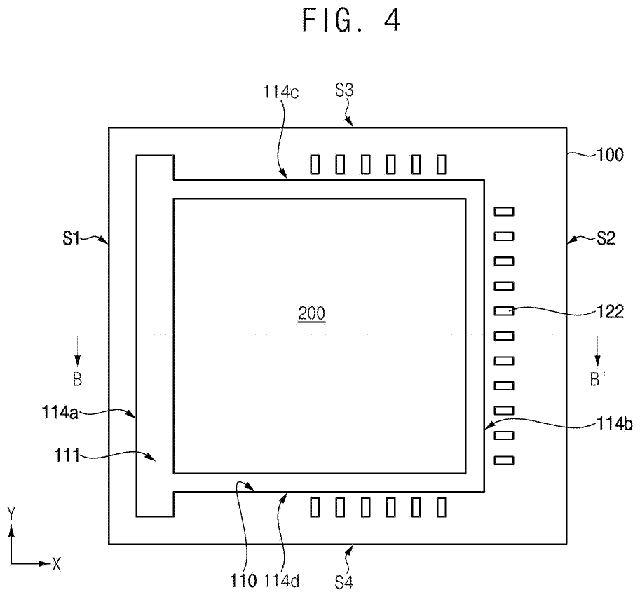

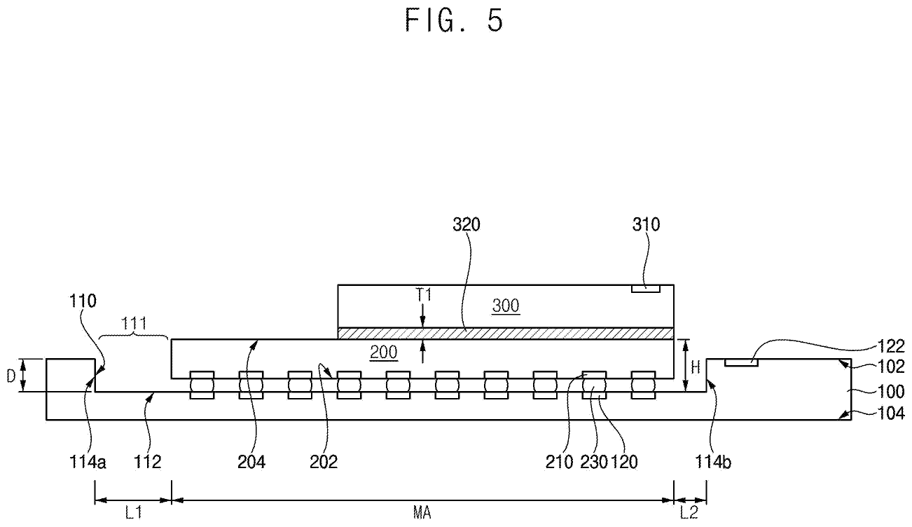

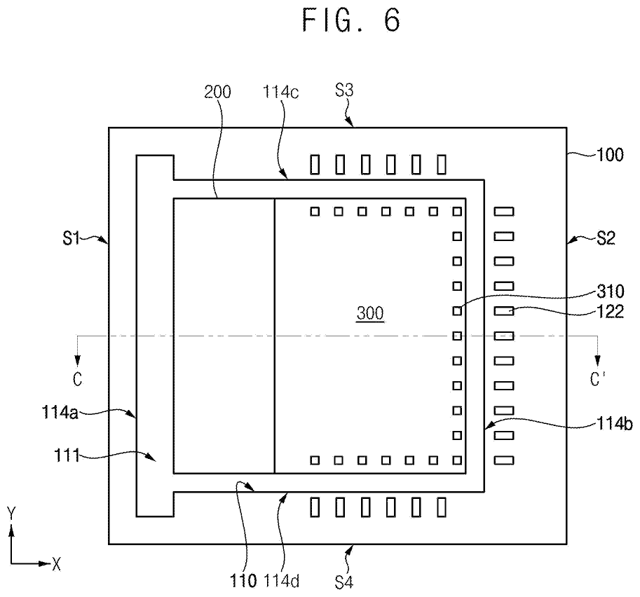

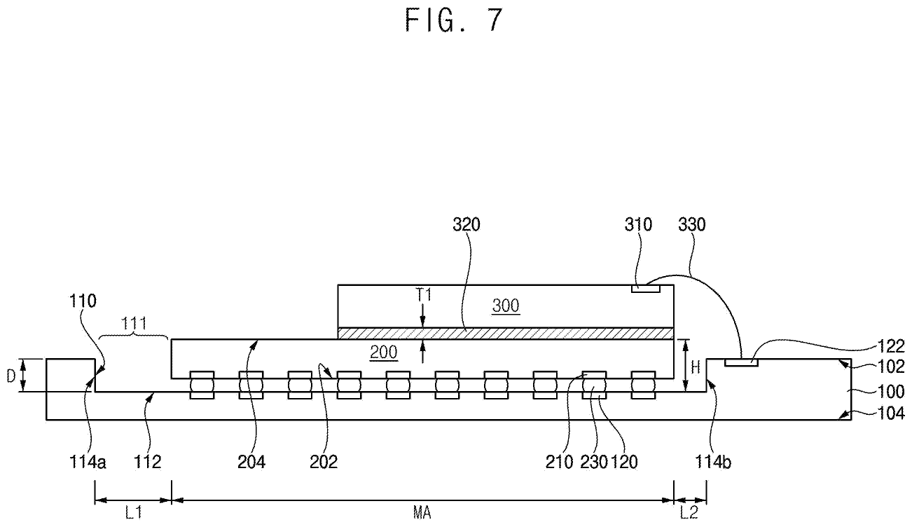

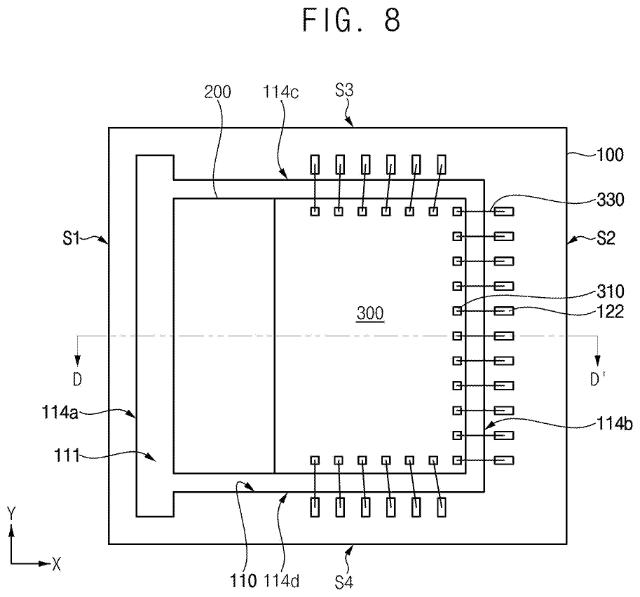

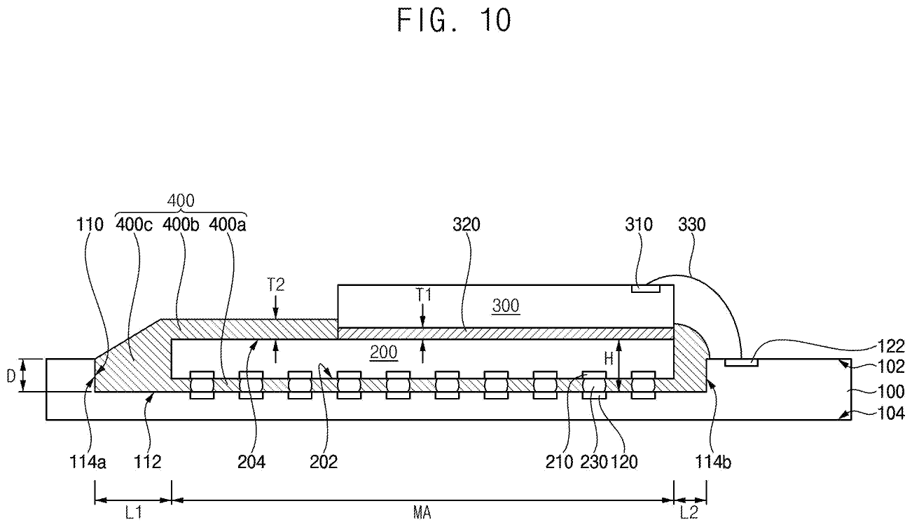

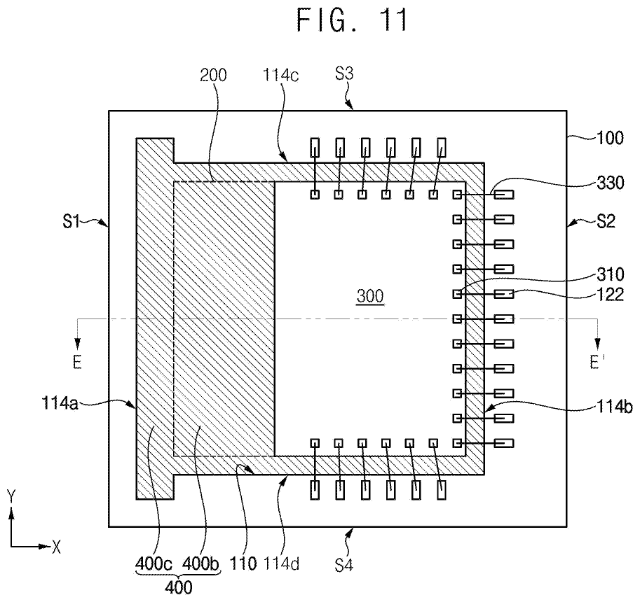

FIGS. 3 to 12 are views illustrating a method of manufacturing a semiconductor package in accordance with example embodiments of the present inventive concept. FIGS. 3, 5, 7, 9, 10, 12 and 13 are cross-sectional views illustrating a method of manufacturing a semiconductor package in accordance with example embodiments of the present inventive concept. FIG. 4 is a plan view of FIG. 3. FIG. 6 is a plan view of FIG. 5. FIG. 8 is a plan view of FIG. 7. FIG. 11 is a plan view of FIG. 10. FIG. 3 is a cross-sectional view taken along the B-B′ in FIG. 4. FIG. 5 is a cross-sectional view taken along the line C-C′ in FIG. 6. FIG. 7 is a cross-sectional view taken along the line D-D′ in FIG. 8. FIG. 10 is a cross-sectional view taken along the line E-E′ in FIG. 11.

Referring to FIGS. 3 and 4, a package substrate 100 having a receiving groove 110 may be provided, and a first semiconductor chip 200 may be mounted in the receiving groove 110 of the package substrate 100.

In example embodiments of the present inventive concept, the package substrate 100 may be a substrate having an upper surface 102 and a lower surface 104 facing each other. For example, the package substrate 100 may include a printed circuit board (PCB), a flexible substrate, a tape substrate, etc. For example, the package substrate 100 may be a multilayer circuit board having vias, conductive layers, and various circuits therein. The package substrate 100 may include internal wirings that serve as channels for electrical connections between the first semiconductor chip 100 and a second semiconductor chip that is to be mounted on the first semiconductor chip 100.

The package substrate 100 may include a first side portion S1 and a second side portion S2 extending in a direction perpendicular to the upper surface 102 and parallel to a second direction (Y direction). The first side portion S1 and the second side portion S2 may face each other. The package substrate 100 may further include a third side portion S3 and a fourth side portion S4 extending in a direction parallel to a first direction (X direction) that is substantially perpendicular to the second direction (Y direction) and facing each other.

The package substrate 100 may have the receiving groove 110. The receiving groove 110 may have a predetermined depth D from the upper surface 102 of the package substrate 100 to a bottom surface 112. When viewed in plan view, the receiving groove 110 may have a shape corresponding to a shape of the first semiconductor chip 200. The receiving groove 110 may have a polygonal shape such as a rectangular shape. The receiving groove 110 includes a first sidewall 114a, a second sidewall 114b, a third sidewall 114c, and a fourth sidewall 114d. The first sidewall 114a may be adjacent to the first side portion S1, and the second sidewall 114b may be adjacent to the second side portion S2. The third sidewall 114c may be adjacent to the third side portion S3, and the fourth sidewall 114d may be adjacent to the fourth side portion S4.

For example, the depth D of the receiving groove 110 may be within a range of about 8 μm to about 20 μm. The depth, location, planar area, etc. of the receiving groove 110 may be determined in consideration of a thickness and planar area of the first semiconductor chip 200, and a thickness of an underfill member that is to be described later with regard to the method. For example, the depth, location, planar area, etc. of the receiving groove 110 may also be determined in consideration of a thickness and planar area of the second semiconductor chip and the molding member that are to be described later with regard to the method.

The receiving groove 110 may have a chip mounting region MA in a central portion thereof. As will be described later, the chip mounting region MA may be a region in which the first semiconductor chip 200 is mounted. The chip mounting region MA may have a rectangular shape.

First substrate pads 120 may be provided in the chip mounting region MA on the bottom surface 112 of the receiving groove 110 and may be electrically connected to the first semiconductor chip 200. The first substrate pads 120 may be arranged in an array form within the chip mounting region MA. Second substrate pads 122 may be provided on the upper surface 102 of the package substrate 100 along the second, third and fourth side portions S2, S3 and S4. The first and second substrate pads 120 and 122 may be respectively connected to the wirings. The wirings may extend on the upper surface 102 or inside the package substrate 100. For example, at least a portion of the wiring may be used as a landing pad or as a substrate pad on the package substrate 100.

Although only some substrate pads are illustrated in the figures, it will be understood that the number, shape, and arrangement of the substrate pads are provided as examples, and the present inventive concept is not limited thereto.

A first insulating layer may be formed on the upper surface 102 of the package substrate 100 to expose the first and second substrate pads 120 and 122. The first insulating layer may cover the upper surface 102 of the package substrate 100 excluding the first and second substrate pads 120 and 122. For example, the first insulating layer may cover the entire upper surface 102 of the package substrate 100 excluding the first and second substrate pads 120 and 122. For example, the first insulating layer may include solder resist.

In example embodiments of the present inventive concept, the first semiconductor chip 200 may be mounted on the mounting region MA within the receiving groove 110 of the package substrate 100 via conductive bumps 230. The first semiconductor chip 200 may be disposed such that a front surface 202 thereof faces the package substrate 100, and the first chip pads 210 may be disposed on the front surface 202, which may be referred to as an active surface. The first semiconductor chip 200 may have a rectangular shape with four sides when viewed in plan view. The first chip pads 210 may be arranged in an array form on the front surface 202 of the first semiconductor chip 200. For example, the first chip pads 210 may be arranged in an array form on the entire front surface 202 of the first semiconductor chip 200.

The first semiconductor chip 200 may be, for example, a logic chip including a logic circuit. The logic chip may be a controller that controls memory chips. The first semiconductor chip 200 may be a processor chip such as ASIC, an application processor (AP), etc. serving as a host such as a CPU, GPU, or SOC. The first semiconductor chip 200 may include, for example, a central processing unit (CPU), a graphics processing unit (GPU), and/or a modem. For example, the first semiconductor chip 200 may be implemented as a modem die or a modem die supporting a WCDMA (Wideband Code Division Multiple Access) communication method, but the present inventive concept is not limited thereto.

The first semiconductor chip 200 may be mounted on the package substrate 100 by using a flip chip bonding method. The first chip pads 210 of the first semiconductor chip 200 may be electrically connected to the first substrate pads 120 of the package substrate 100 by the conductive bumps 230, for example, solder bumps.

For example, a thickness of the first semiconductor chip 200 may be within a range of about 40 μm to about 110 μm. The first semiconductor chip 200 may have a predetermined height H from the bottom surface 112 of the receiving groove 110 to the upper surface 204 of the first semiconductor chip 200. The height H of the first semiconductor chip 200 may be within a range of about 50 μm to about 110 μm. The first semiconductor chip 200 may protrude from the upper surface 102 of the package substrate 100.

When viewed in plan view, a first distance L1 between the first semiconductor chip 200 and the first sidewall 114a of the receiving groove 110 may be greater than a second distance L2 between the first semiconductor chip 200 and the second sidewall 114b of the receiving groove 110. As will be described later, a supply portion 111 through which an aqueous underfill solution is supplied may be provided between the first semiconductor chip 200 and the first sidewall 114a of the receiving groove 110. For example, the first distance L1 between the first semiconductor chip 200 and the first sidewall 114a of the receiving groove 110 may be within a range of about 100 μm to about 250 μm.

Referring to FIGS. 5 and 6, a second semiconductor chip 300 may be attached to the first semiconductor chip 200 by using an adhesive film 320. The second semiconductor chip 200 may be attached to a backside surface of the first semiconductor chip 200 by using the adhesive film 320 such as a die attach film (DAF) by a die attach process. The second semiconductor chip 300 may be disposed such that the backside surface thereof faces the first semiconductor chip 200, and second chip pads 310 may be disposed on a front surface of the second semiconductor chip 300, opposite to the backside surface. The backside surface may be an inactive surface. The second semiconductor chip 300 may have a rectangular shape with four sides when viewed in plan view.

For example, a thickness of the second semiconductor chip 300 may be within a range of about 40 μm to about 110 μm. A thickness T1 of the adhesive film 320 may be within a range of about 10 μm to about 30 μm. The second semiconductor chip 300 may include, for example, a memory chip including a memory circuit. For example, the second semiconductor chip may include volatile memory devices such as SRAM devices, DRAM devices, and non-volatile memory devices such as flash memory devices, PRAM devices, MRAM devices, RRAM devices.

In example embodiments of the present inventive concept, the second semiconductor chip 300 may be stacked to expose a portion of the upper surface 204 of the first semiconductor chip 200. For example, an area of the second semiconductor chip 300 may be less than an area of the first semiconductor chip 200. An outer surface of the second semiconductor chip 300 and an outer surface of the first semiconductor chip 200 adjacent to the second sidewall 114b of the receiving groove 110 may be positioned on the same plane. Accordingly, the second semiconductor chip 300 may expose a side portion of the first semiconductor chip 200 adjacent to the first sidewall 114a of the receiving groove 110.

In example embodiments of the present inventive concept, the second semiconductor chip 300 may be offset-aligned in a horizontal direction on the first semiconductor chip 200. The second semiconductor chip 300 may be offset-aligned in the second direction (X direction) to expose one side portion of the first semiconductor chip 200 adjacent to the first sidewall 114a of the receiving groove 110. For example, a center of the second semiconductor chip 300 may be misaligned with a center of the first semiconductor chip 200.

Referring to FIGS. 7 and 8, the second semiconductor chip 300 may be electrically connected to the package substrate 100 through conductive connection members 330.

In example embodiments of the present inventive concept, a wire bonding process may be performed to connect the second chip pads 310 of the second semiconductor chip 300 to the second substrate pads 122 that are disposed on the upper surface 102 of the package substrate 100 by using bonding wires 330.

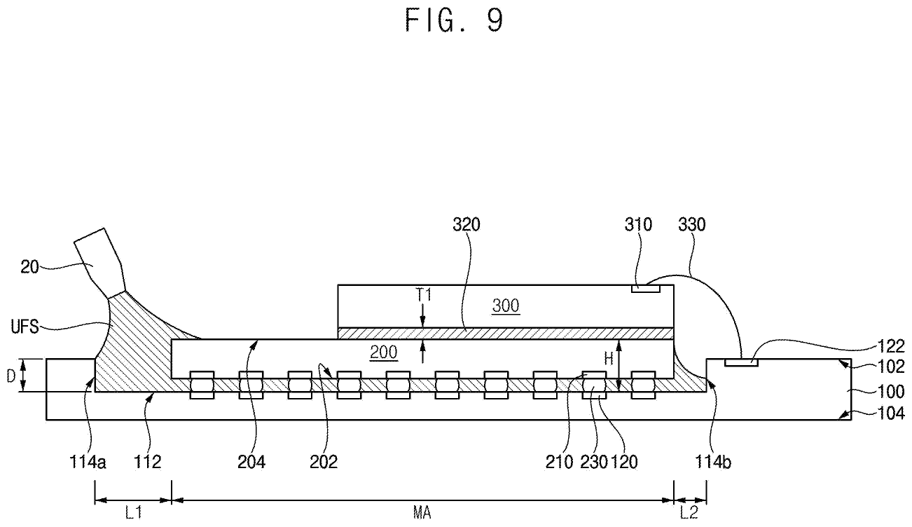

Referring to FIGS. 9 to 11, an underfill member 400 may be formed between the first semiconductor chip 200 and the bottom surface of the receiving groove 110 within the receiving groove 110 of the package substrate 100 and may cover the portion of the upper surface 204 of the first semiconductor chip 200 that is exposed by the second semiconductor chip 300.

As illustrated in FIG. 9, a dispenser nozzle 20 may dispense an underfill aqueous solution (UFL) into the receiving groove 110 while moving in the second direction along the supply portion 111 that is between the first semiconductor chip 200 and the first sidewall 114a of the receiving groove 110. For example, the aqueous underfill solution may include an epoxy material. The underfill aqueous solution may flow between the first semiconductor chip 200 and the first to fourth sidewalls 114a, 114b, 114c and 114d of the receiving groove 110 and between the first semiconductor chip 200 and the bottom surface 112 the receiving groove 110. In addition, the underfill aqueous solution may flow along the outer surface of the first semiconductor chip 200 onto the exposed upper surface 204 of the first semiconductor chip 200, and then, may be cured to form the underfill member 400.

As illustrated in FIGS. 10 and 11, the underfill member 400 may include a first cover portion 400a, a second cover 400b, and a third cover portion 400c. The first cover portion 400a may fill a gap between the first semiconductor chip 200 and the bottom surface 112 of the receiving groove 110, and the second cover portion 400b may cover the exposed upper surface 204 of the first semiconductor chip 200. The third cover portion 400c may fill a gap between the first semiconductor chip 200 and the first to fourth sidewalls 114a, 114b, 114c, and 114d of the receiving groove 110.

The third cover portion 400c may cover the outer surface of the first semiconductor chip 200. The second cover portion 400b may cover the exposed upper surface 204 of the first semiconductor chip 200 that is exposed by the second semiconductor chip 300. The second cover portion 400b may cover a side surface of the adhesive film 320 that is disposed below the second semiconductor chip 300. For example, a thickness T2 of the second cover portion 400b may be within a range of about 5 μm to about 30 μm.

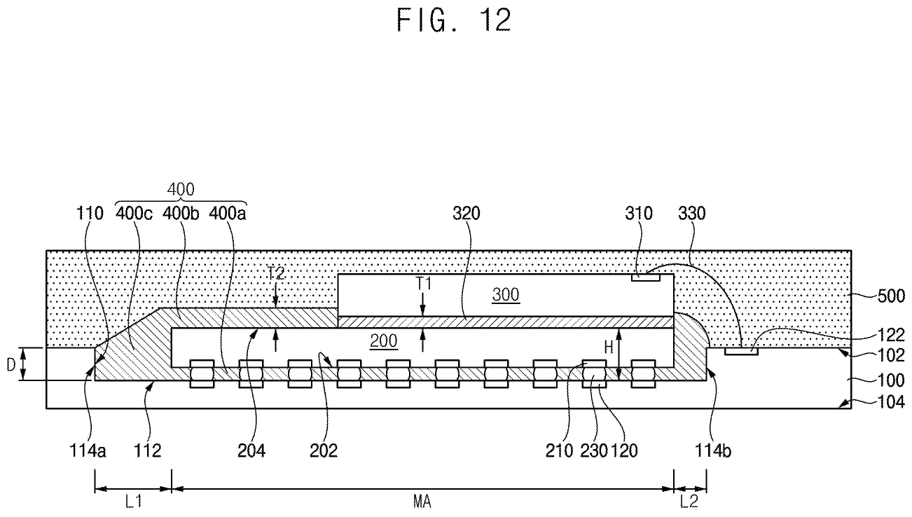

Referring to FIG. 12, a molding member 500 may be formed on the upper surface 102 of the package substrate 100 to cover the first and second semiconductor chips 200 and 300 and the underfill member 400.

In example embodiments of the present inventive concept, the molding member 500 may be formed through a molding process using a transfer mold. For example, the molding member 500 may include epoxy mold compound (EMC).

Since the second cover portion 400b of the underfill member 400 covers the side surface of the adhesive film 320 that is disposed below the second semiconductor chip 300, it may be possible to prevent the adhesive film 320 from being peeled off from the first semiconductor chip 200 when the molding member 500 is formed by the molding process using the transfer mold.

Then, external connection members 600 may be formed on external connection pads that are disposed on the lower surface 104 of the package substrate 100 to complete a semiconductor package 10 of FIG. 1.

For example, the external connection members 600 may include solder balls. The external connection members 600 may be respectively formed on the external connection pads that are disposed on the lower surface 104 of the package substrate 100 through a solder ball attach process.

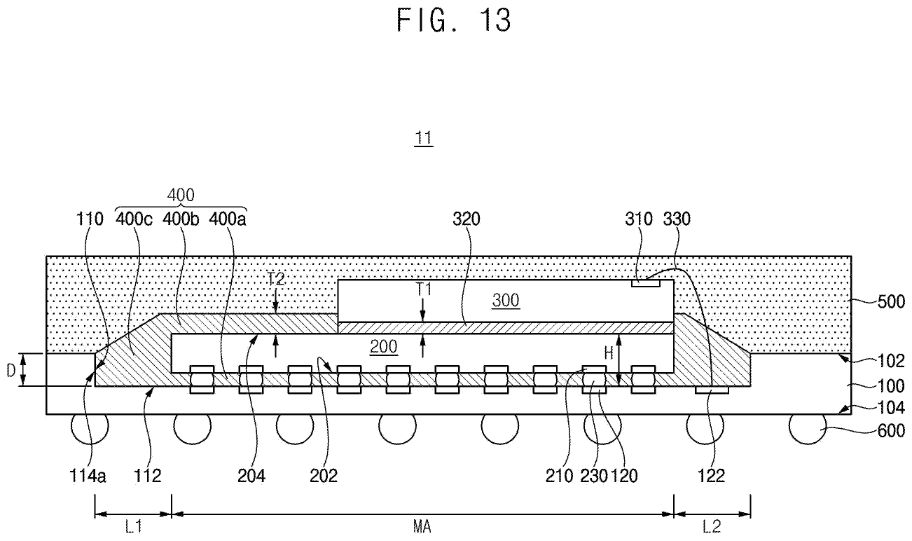

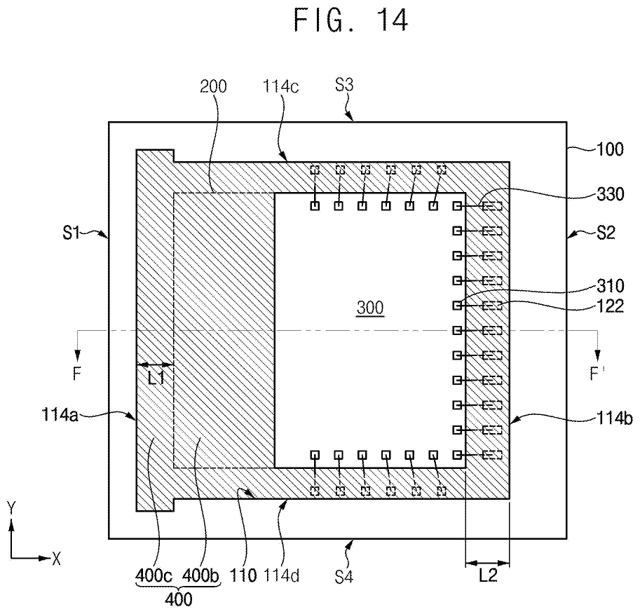

FIG. 13 is a cross-sectional view illustrating a semiconductor package in accordance with example embodiments of the present inventive concept. FIG. 14 is a plan view of FIG. 13. FIG. 13 is a cross-sectional view taken along the line F-F′ in FIG. 14. The semiconductor package may be substantially the same as the semiconductor package described with reference to FIGS. 1 and 2 except for arrangements of second bonding pads and bonding wires. Thus, same reference numerals may be used to refer to the same or like elements and any further repetitive explanation or description concerning the above elements may be omitted or briefly discussed.

Referring to FIGS. 13 and 14, a package substrate 100 of a semiconductor package 11 may have a receiving groove 110 that has a predetermined depth D from an upper surface 102 of the package substrate 100. The receiving groove 110 may have a chip mounting region MA in a central portion in which a first semiconductor chip 200 is mounted. The chip mounting region MA may have a rectangular shape corresponding to a shape of the first semiconductor chip 200.

In example embodiments of the present inventive concept, the package substrate 100 includes first substrate pads 120 and second substrate pads 122. The first substrate pads 120 are for electrical connection with the first semiconductor chip 200, and the second substrate pads 122 are for electrical connection with a second semiconductor chip 300. The first substrate pads 122 may be provided in the chip mounting region MA and on a bottom surface 112 of the receiving groove 110. The first substrate pads 120 may be arranged in an array form within the chip mounting region MA. The second substrate pads 122 may be provided outside the chip mounting region MA and on the bottom surface 112 of the receiving groove 110. The second substrate pads 122 may be arranged to be spaced apart from each other along second to fourth sidewalls 114b, 114c and 114d of the receiving groove 110.

In example embodiments of the present inventive concept, bonding wires 330 may electrically connect second chip pads 310 of the second semiconductor chip 300 and the second substrate pads 122 that are disposed on the bottom surface 112 of the receiving groove 110 of the package substrate 100. A third cover portion 400c of an underfill member 400 may cover portions of the bonding wires 330 that extend upward from the second substrate pads 122. Accordingly, a lower portion of the bonding wire 330 may be covered by the third cover portion 400c of the underfill member 400, and an upper portion of the bonding wire 330 may be exposed by the third cover portion 400c of the underfill member 400 and may be covered by a molding member 500.

As mentioned above, the package substrate 100 of the semiconductor package 11 may include the second substrate pads 122 that are positioned on the bottom surface 112, outside of the chip mounting region MA, of the receiving groove 110 and are spaced apart from each other along the second sidewall 114b of the receiving groove 110. The third cover portion 400c of the underfill member 400 may cover the lower portions of the bonding wires 330 that extend upward from the second substrate pads 122.

Accordingly, wire sweeping may be prevented during the transfer molding process, to thereby prevent tearing and electrical shortages of the bonding wires 330.

Hereinafter, a method of manufacturing the semiconductor package of FIG. 13 according to example embodiments of the present inventive concept will be described.

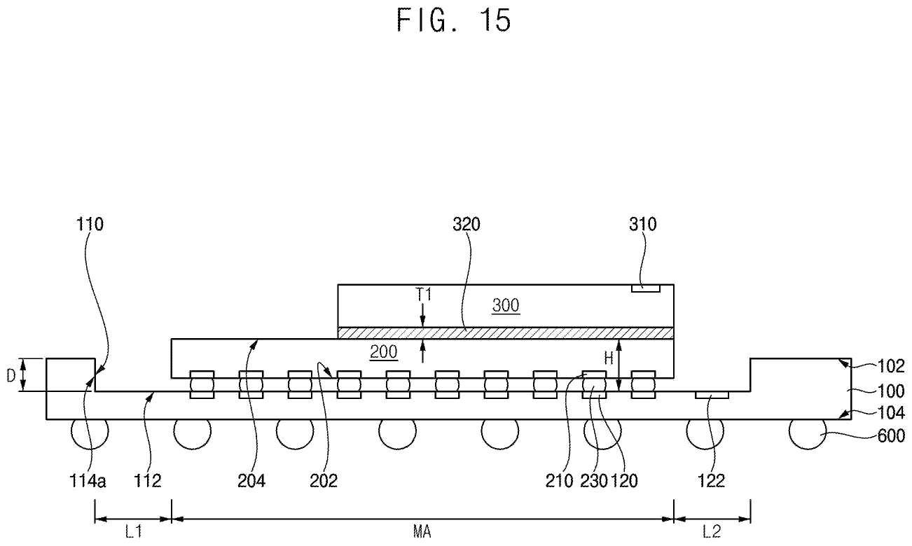

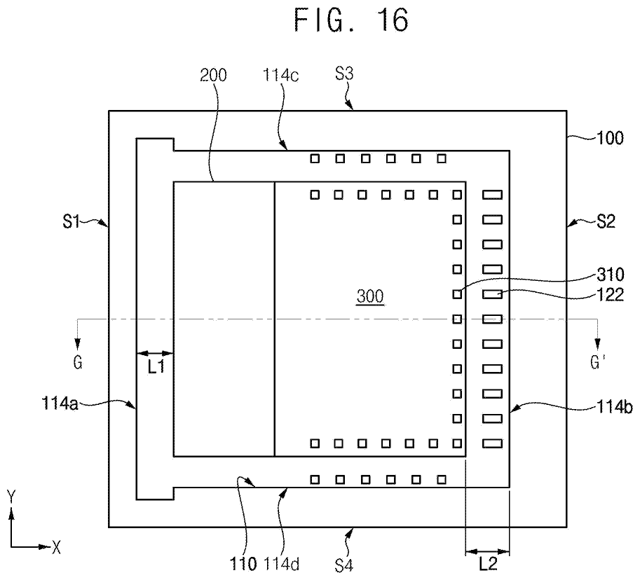

FIGS. 15 to 18 are views illustrating a method of manufacturing a semiconductor package in accordance with example embodiments of the present inventive concept. FIGS. 15, 17 and 18 are cross-sectional views illustrating a method of manufacturing a semiconductor package in accordance with example embodiments of the present inventive concept. FIG. 16 is a plan view of FIG. 15. FIG. 15 is a cross-sectional view taken along the line G-G′ in FIG. 16. It will be understood that same reference numerals may be used to refer to the same or like elements, and repetitive explanations or descriptions may be omitted or briefly discussed.

Referring to FIGS. 15 and 16, a package substrate 100 having first and second substrate pads 120 and 122 that are provided on a bottom surface 112 of a receiving groove 110 may be provided, and processes the same as or similar to the processes described with reference to FIGS. 3 to 6 may be performed to mount a first semiconductor chip 200 in the receiving groove 110 of the package substrate 100, and a second semiconductor chip 300 may be stacked on the first semiconductor chip 200.

In example embodiments of the present inventive concept, the package substrate 100 may include first substrate pads 120, which are for electrical connection with the first semiconductor chip 200, and second substrate pads 122, which are for electrical connection with the second semiconductor chip 300. The first substrate pads 120 may be provided in a chip mounting region MA and on the bottom surface 112 of the receiving groove 110. The first substrate pads 120 may be arranged in an array form within the chip mounting region MA. The second substrate pads 122 may be provided outside the chip mounting region MA and on the bottom surface 112 of the receiving groove 110. The second substrate pads 122 may be arranged to be spaced apart from each other along second to fourth sidewalls 114b, 114c and 114d of the receiving groove 110.

The first semiconductor chip 200 may be mounted on the chip mounting region MA within the receiving groove 110 of the package substrate 100 by a flip chip bonding method. The first semiconductor chip 200 may be disposed such that a front surface 202 thereof faces the package substrate 100, and the first chip pads 210 may be disposed on the front surface 202, which may be referred to as an active surface. The first semiconductor chip 200 may be mounted on the first substrate pads 120 that are disposed on the bottom surface 112 of the receiving groove 110 via conductive bumps 230 that are formed on the first chip pads 210.

Then, the second semiconductor chip 300 may be attached to the first semiconductor chip 200 by using an adhesive film 320. The third semiconductor chip 300 may be attached to a backside surface of the first semiconductor chip 200 by using the adhesive film 320 such as a die attach film (DAF) through a die attach process. The second semiconductor chip 300 may be disposed such that a backside surface thereof faces the first semiconductor chip 200, and second chip pads 310 may be disposed on a front surface of the second semiconductor chip 300, opposite to the backside surface. The backside surface may be an inactive surface.

The second semiconductor chip 300 may be stacked to expose a portion of the upper surface 204 of the first semiconductor chip 200. For example, an area of the second semiconductor chip 300 may be smaller than an area of the first semiconductor chip 200. An outer surface of the second semiconductor chip 300 that is adjacent to the second sidewall 114b of the receiving groove 110 and an outer surface of the first semiconductor chip 200 may be positioned on the same plane. Accordingly, the second semiconductor chip 300 may expose one side portion of the first semiconductor chip 200 that is adjacent to a first sidewall 114a of the receiving groove 110.

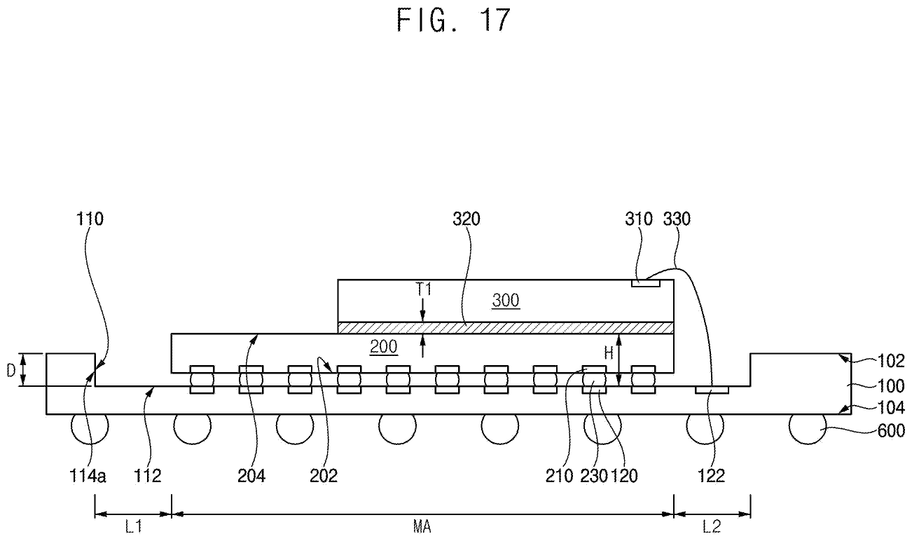

Referring to FIG. 17, processes the same as or similar to the processes described with reference to FIGS. 7 and 8 may be performed to electrically connect the second semiconductor chip 300 to the package substrate 100 by conductive connection members 330.

In example embodiments of the present inventive concept, a wire bonding process may be performed to connect the second chip pads 310 of the second semiconductor chip 300 to the second substrate pads 122 that are disposed on the bottom surface 112 the receiving groove 110 of the package substrate 100 by using bonding wires 330.

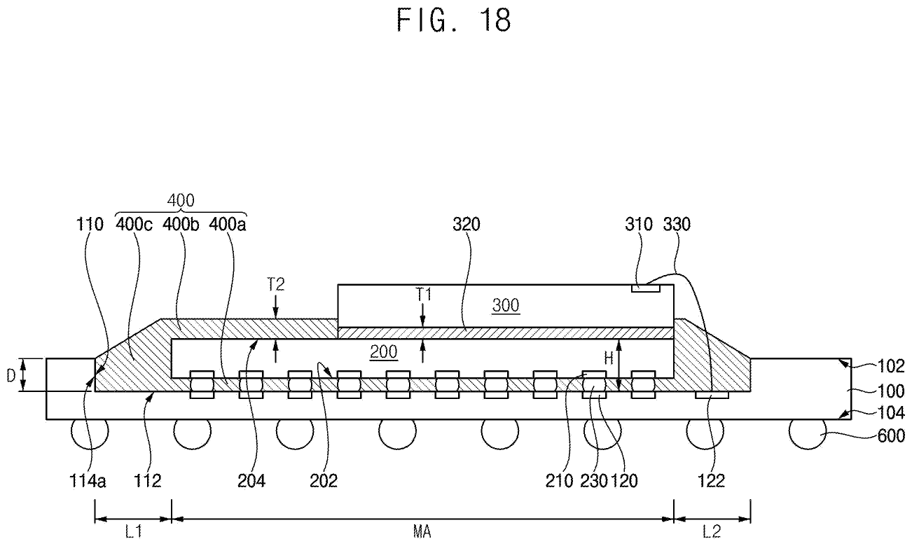

Referring to FIG. 18, processes the same as or similar to the processes described with reference to FIGS. 9 to 11 may be performed to form an underfill member 400 in the receiving groove 110 of the package substrate 100.

In example embodiments of the present inventive concept, a third cover portion 400c of the underfill member 400 may fill a gap between the first semiconductor chip 200 and the first to fourth sidewalls 114a, 114b, 114c and 114d of the receiving groove 110. The third cover portion 400c of the underfill member 400 may cover portions of the bonding wires 330 that extend upward from the second substrate pads 122. Accordingly, a lower portion of the bonding wire 330 may be covered by the third cover portion 400c of the underfill member 400, and an upper portion of the bonding wire 330 may be exposed by the third cover portion 400c of the underfill member 400.

A second cover portion 400b of the underfill member 400 may cover the portion of the second (e.g., the upper) surface 204 of the first semiconductor chip 200 that is exposed by the second semiconductor chip 300. The second cover portion 400b may cover a side surface of the adhesive film 320 that is disposed below the second semiconductor chip 300. The second cover portion 400b may cover a lower sidewall of the second semiconductor chip 300.

Then, processes the same as or similar to the processes described with reference to FIG. 12 may be performed to form a molding member 500 (see FIG. 13) to cover the first and second semiconductor chips 200 and 300 and the underfill member 400 on the upper surface 102 of the package substrate 100. The molding member 500 may be formed by a molding process by using a transfer mold.

Since the third cover portion 400c of the underfill member 400 covers the lower portions of the bonding wires 330 that extend upward from the second substrate pads 122, wire sweeping may be prevented to thereby prevent tearing and electrical shortages of the bonding wires 330 during the transfer molding process.

Since the second cover portion 400b of the underfill member 400 covers the side surface of the adhesive film 320 that is disposed below the second semiconductor chip 300, it may be possible to prevent the adhesive film 320 from being peeled off from the first semiconductor chip 200 when the molding member 500 is formed by the molding process by using the transfer mold.

Then, external connection members 600 may be formed on external connection pads that are disposed on the lower surface 104 of the package substrate 100 to complete a semiconductor package 11 of FIG. 13.

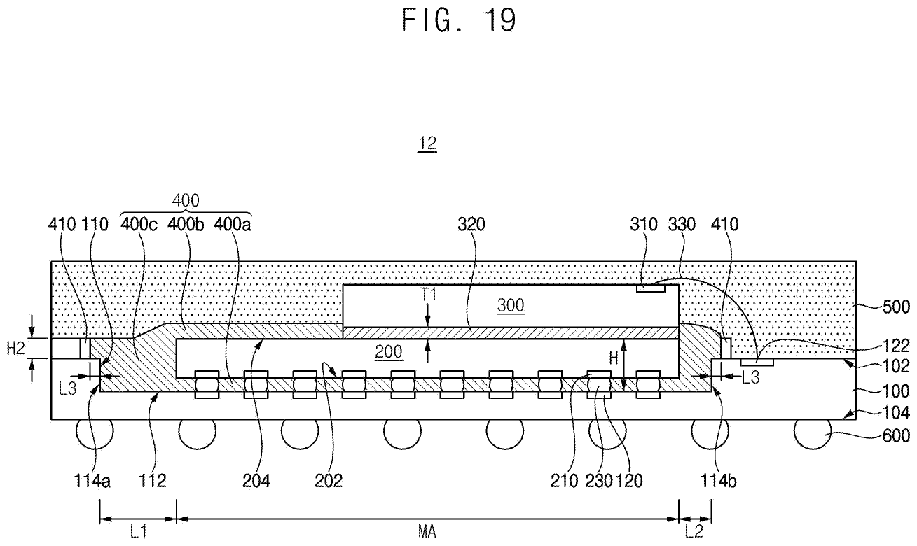

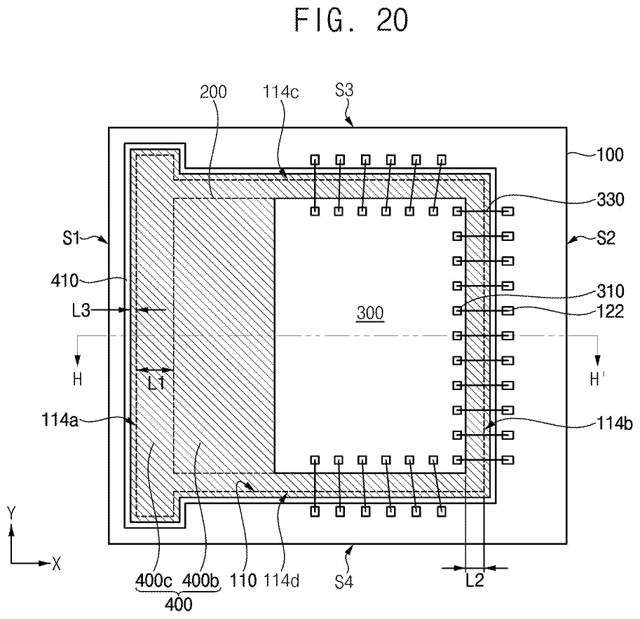

FIG. 19 is a cross-sectional view illustrating a semiconductor package in accordance with example embodiments of the present inventive concept. FIG. 20 is a plan view of FIG. 19. FIG. 19 is a cross-sectional view taken along the line G-G′ in FIG. 20. The semiconductor package is substantially the same as the semiconductor package described with reference to FIGS. 1 and 2 except for arrangements of second substrate pads and bonding wires. Thus, same reference numerals may be used to refer to the same or like elements and any further repetitive explanation or description concerning the above elements may be omitted or briefly discussed.

Referring to FIGS. 19 and 20, a semiconductor package 13 may further include a dam structure 410 that extends around a receiving groove 110 and that may be disposed on an upper surface 102 of a package substrate 100.

In example embodiments of the present inventive concept, the dam structure 410 may extend from the upper surface 102 of the package substrate 100 to have a predetermined height H2 and may extend along a circumference of the receiving groove 110 to cover a side surface of a portion of an underfill member 400 that protrudes from the receiving groove 110. For example, the portion of the underfill member 400 may protrude beyond the upper surface 102 of the package substrate 100.

An upper surface of the dam structure 410 may be positioned higher than an upper surface 204 of the first semiconductor chip 200. The height H2 of the dam structure 410 from the upper surface 102 of the package substrate 100 may be at least 200 μm, about. The dam structure 410 may be spaced apart from the first to fourth sidewalls 114a, 114b, 114c and 114d of the receiving groove 110 by a predetermined distance L3. The spacing distance L3 of the dam structure 410 may be at least 450 μm, about.

Since the dam structure 410 accommodates a larger amount of underfill aqueous solution when forming the underfill member 400, the underfill member 400 covering the exposed upper surface of the first semiconductor chip 200 may be easily formed.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package, comprising:
a package substrate having an upper surface and a lower surface opposite the upper surface, wherein the package substrate has a receiving groove that has a predetermined depth from the upper surface;
a first semiconductor chip disposed in the receiving groove of the package substrate, wherein a first surface of the first semiconductor chip faces the package substrate, and first chip pads are formed on the first surface;
a second semiconductor chip attached to a second surface opposite to the first surface of the first semiconductor chip by an adhesive film, wherein the second semiconductor chip does not overlap a portion of the second surface of the first semiconductor chip;
an underfill member filling the receiving groove of the package substrate, wherein the underfill member includes a first cover portion and a second cover portion, wherein the first cover portion fills a gap between the first semiconductor chip and a bottom surface of the receiving groove, and the second cover portion covers the portion of the second surface of the first semiconductor chip that is not overlapped by the second semiconductor chip; and
a molding member covering the first semiconductor chip, the second semiconductor chip and the underfill member and disposed on the package substrate.

2. The semiconductor package of claim 1, wherein the second cover portion of the underfill member covers a side surface of the adhesive film that is disposed below the second semiconductor chip.

3. The semiconductor package of claim 1, wherein a thickness of the second cover portion of the underfill member is within a range of about 5 μm to about 30 μm.

4. The semiconductor package of claim 1, wherein the underfill member includes an epoxy material.

5. The semiconductor package of claim 1, wherein the adhesive film includes a die attach film.

6. The semiconductor package of claim 1, wherein the first semiconductor chip is mounted on first substrate pads via conductive bumps that are formed on the first chip pads of the first semiconductor chip, wherein the first substrate pads are disposed on the bottom surface of the receiving groove.

7. The semiconductor package of claim 1, wherein a fourth surface of the second semiconductor chip faces the first semiconductor chip, and second chip pads are formed on a third surface, opposite to the fourth surface, of the second semiconductor chip.

8. The semiconductor package of claim 7, further comprising:
bonding wires electrically connecting the second chip pads of the second semiconductor chip to second substrate pads of the package substrate.

9. The semiconductor package of claim 8, wherein the second substrate pads are provided on the bottom surface of the receiving groove.

10. The semiconductor package of claim 1, further comprising:
a dam structure that protrudes to have a predetermined height on the upper surface of the package substrate and extends along a circumference of the receiving groove to cover a portion of the underfill member that protrudes from the receiving groove.

11. A semiconductor package, comprising:
a package substrate having a receiving groove that has a predetermined depth from on an upper surface of the package substrate;
a first semiconductor chip disposed in the receiving groove of the package substrate;
a second semiconductor chip attached to an upper surface of the first semiconductor chip by an adhesive film to expose a portion of the upper surface of the first semiconductor chip;
an underfill member filling the receiving groove of the package substrate, wherein the underfill member includes a first cover portion, a second cover portion, and a third cover portion, wherein the first cover portion fills a gap between the first semiconductor chip and the bottom of the receiving groove, the second cover portion covers the portion of the upper surface of the first semiconductor chip that is exposed by the second semiconductor chip, and the third cover portion covers a gap between the first semiconductor chip and a sidewall of the receiving groove; and
a molding member covering the first semiconductor chip, the second semiconductor chip, and the underfill member and disposed on the package substrate.

12. The semiconductor package of claim 11, wherein the second cover portion of the underfill member covers a side surface of the adhesive film that is disposed below the second semiconductor chip.

13. The semiconductor package of claim 11, wherein a thickness of the second cover portion of the underfill member is within a range of about 5 μm to about 30 μm.

14. The semiconductor package of claim 11, wherein the first semiconductor chip is mounted on first substrate pads via conductive bumps that are formed on the first chip pads of the first semiconductor chip, wherein the first substrate pads are disposed on the bottom surface of the receiving groove.

15. The semiconductor package of claim 11, wherein a fourth surface of the second semiconductor chip faces the first semiconductor chip, and second chip pads are formed on a third surface, opposite to the fourth surface, of the second semiconductor chip.

16. The semiconductor package of claim of claim 15, further comprising:
bonding wires electrically connecting the second chip pads of the second semiconductor chip to second substrate pads of the package substrate.

17. The semiconductor package of claim 16, wherein the second substrate pads are provided on the bottom surface of the receiving groove.

18. The semiconductor package of claim 11, further comprising:
a dam structure that protrudes to have a predetermined height on the upper surface of the package substrate and extends along a circumference of the receiving groove to cover a portion of the underfill member that protrudes from the receiving groove.

19. The semiconductor package of claim 11, wherein the adhesive film includes a die attach film.

20. A semiconductor package, comprising:
a package substrate having a receiving groove that has a predetermined depth from an upper surface of the package substrate;
a first semiconductor chip disposed in the receiving groove of the package substrate, wherein a first surface of the first semiconductor chip faces the package substrate, wherein first chip pads are disposed on the first surface of the first semiconductor chip, wherein the first semiconductor chip is mounted on first substrate pads through conductive bumps that are formed on the first chip pads of the first semiconductor chip, wherein the first substrate pads are disposed on the bottom surface of the receiving groove;
a second semiconductor chip attached on a second surface opposite to the first surface of the first semiconductor chip by an adhesive film to expose a portion of the second surface of the first semiconductor chip, wherein a fourth surface of the second semiconductor chip faces the first semiconductor chip, and second chip pads are formed on a third surface, opposite to the fourth surface, of the second semiconductor chip;
an underfill member filling the receiving groove of the package substrate, wherein the underfill member includes a first cover portion and a second cover portion, wherein the first cover portion fills a gap between the first semiconductor chip and the bottom surface of the receiving groove, and the second cover portion covers the portion of the second surface of the first semiconductor chip that is exposed by the second semiconductor chip; and
a molding member covering the first semiconductor chip, the second semiconductor chip, and the underfill member and disposed on the package substrate,
wherein a thickness of the second cover portion of the underfill member is within a range of about 5 μm to about 30 μm.
